(19) United States
(12) Patent Application Publication
(10) Pub. No.: US 2006/0086945 A1
(43) Pub. Date: Apr. 27, 2006

(54) Package structure for optical-electrical semiconductor

(75) Inventors: Bily Wang, Hsin Chu City (TW); Jonnie Chuang, Pan Chiao City (TW); Shih-Yu Wu, Pan Chiao City (TW); Ching-Hung Ko, Tai Nan City (TW); Chun-Cheng Weng, Tao Yuan Hsien (TW)

Correspondence Address: TROXELL LAW OFFICE PLLC, SUITE 1404, 5205 LEESBURG PIKE, FALLS CHURCH, VA, 22041, US

(73) Assignee: Harvatek Corporation

(21) Appl. No.: 10/973,408

(22) Filed: Oct. 27, 2004

(51) Int. Cl. H01L 33/00

(52) U.S. Cl. 257/99

(57) ABSTRACT

A package structure for an optical-electrical semiconductor is described. The package structure has a thermal conductive structure for heat transfer and is integrally formed in one piece to improve the structural strength thereof, while the thermal conductive structure prevent over-heating of the LED device for greater longevity. The package structure reduces the failure rate in production and has improved quality. When the present invention is applied in light-emitting diode packages, the special requirement can be reached and has better properties than the prior art.

### BACKGROUND OF THE INVENTION

1. Field of the Invention

The present invention relates to a package structure for an optical-electrical semiconductor. The benefit of the present invention is that the thermal conductive structure for heat transfer is integrally formed in one body. The effect of the present invention can reduce the failure rate of production, improve the quality thereof, and decrease structural deformation. When the present invention is applied in a light-emitting diode package, the special requirement can be reached and has better properties than the prior art. The main feature of the present invention is integral formation in one structure to improve the structural strength with a thermal conductive structure to prevent overheating of the LED device for long use and avoiding waste in the assembly procedure.

2. Description of Related Art

In the industry of chip packaging, one special object for a skilled person is a package for an optical-electrical semiconductor. In addition, the packaging industry for light-emitting diodes and optical sensors is a very important subject for the requirement of high quality (such as a small size with the same function of the old product). The importance of the package for an optical-electrical semiconductor is very obvious when compared with the package of traditional semiconductor. The new technology promotion for semiconductor package is still proceeding to new requirements (such as an LED with two leads or four leads). More leads in a package usually means more special requirements for the semiconductor package. Further, the brightness of an LED is a very important issue for the LED package.

As is known by persons skilled in the relevant field, the technology of a semiconductor package mainly uses wire bonding or connection together with the packaging by special a cover material to form an electrical component structure with some special function. The main functions of the semiconductor package are power distribution, signal distribution, heat dissipation and protection and support. A very obvious case can be observed for the package of a semiconductor IC or a light-emitting diode.

Reference is made FIG. 1, which is a schematic diagram of a conventional package structure for a light-emitting diode 1a. The embedded injection body 10a connects to heat conduction material 30a to adhere with the LED chip 20a on the cup surface 40a (on the base 50a) with connection with the leads 11a. The conventional assembly procedure suffers from drawbacks, and the cup wall (surrounding the cup surface 40a) reflects light (like the reflection cup of a electric flashlight) without focusing to a point. The lens 12a is suited to a point-shaped light source. Light dissipation thus occurs to affect the precision of light radiation scope on focusing. Further, the base 50a is not integral with the embedded injection body 10a and is expensive to assemble.

### SUMMARY OF THE INVENTION

The major purpose of present invention is to provide a package structure with simple structure with high-quality light focusing for an optical-electrical semiconductor, and particularly for LEDs, that is suitable for cheap, high quality mass production.

To achieve the above purpose, the present invention discloses a packaging structure that is formed in one piece as shell with a chip-receiving device (without the cup wall for light reflection) and further uses heat-conducting material for heat dissipation. The present invention also is easy to manufacture on conventional packaging machines.

The present invention consists of a shell body having a heat conductive body and a lead, the shell body being formed in one piece, a piece of heat-conductive laminate, an optical-electrical semiconductor structure attached on the plane of the internal side of the shell body with heat-conductive laminate, and a lens device formed from transparent material.

To provide a further understanding of the invention, the following detailed description illustrates embodiments and examples of the invention, this detailed description being provided only for illustration of the invention.

### BRIEF DESCRIPTION OF DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a schematic diagram of a conventional package for a light-emitting diode;

FIG. 2A is a schematic top view of an embodiment of the present invention;

FIG. 2B is a schematic cross-sectional front view of an embodiment of the present invention;

FIG. 2C is a schematic side view of an embodiment of the present invention;

FIG. 3A is a schematic top view of an embodiment of the present invention;

FIG. 3B is a schematic, cross-sectional view of an embodiment of the present invention;

FIG. 3C is a schematic side view of an embodiment of the present invention;

FIG. 4A is a schematic top view of an embodiment of the present invention;

FIG. 4B is a schematic, cross-sectional front view of an embodiment of the present invention; and

FIG. 4C is a schematic side view of another embodiment of the present invention.

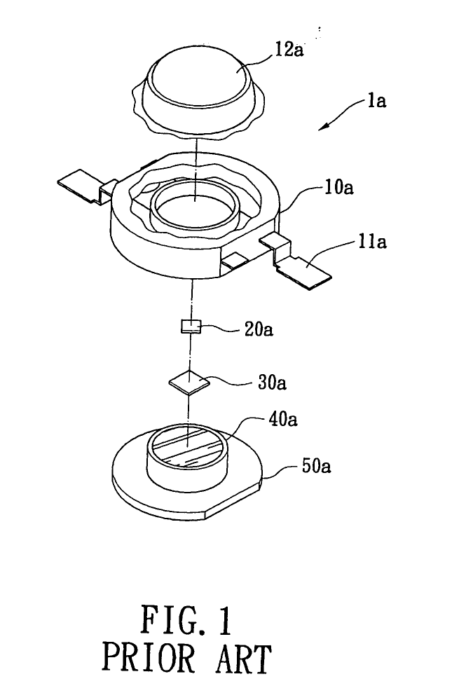

### DESCRIPTION OF THE PREFERRED EMBODIMENTS

The basic principle of the invention is use a lens to focus light to a point (or a local region) to raise the quality of light radiation and remove an unnecessary component (such as the cup wall for light reflection in the prior art). The present invention is especially applicable to situation where high quality light (or image) must be focused on a local area (such as scanner or digital camera). In addition, the present invention uses a shell body integrally formed in one piece for a good heat conduction effect and ease of assembly.

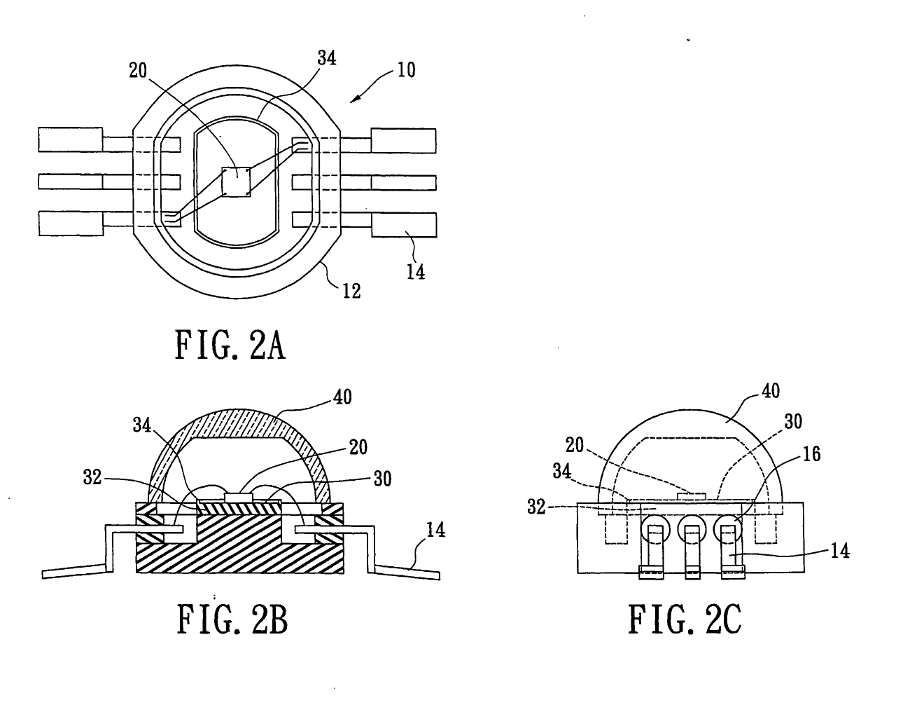

In addition, the present invention also can use wire bonding as a packaging method, as illustrated in FIG. 2A and FIG. 2B. The present invention also can use an optical-electrical product having an outer transparent polymer coating (like a SMT product).

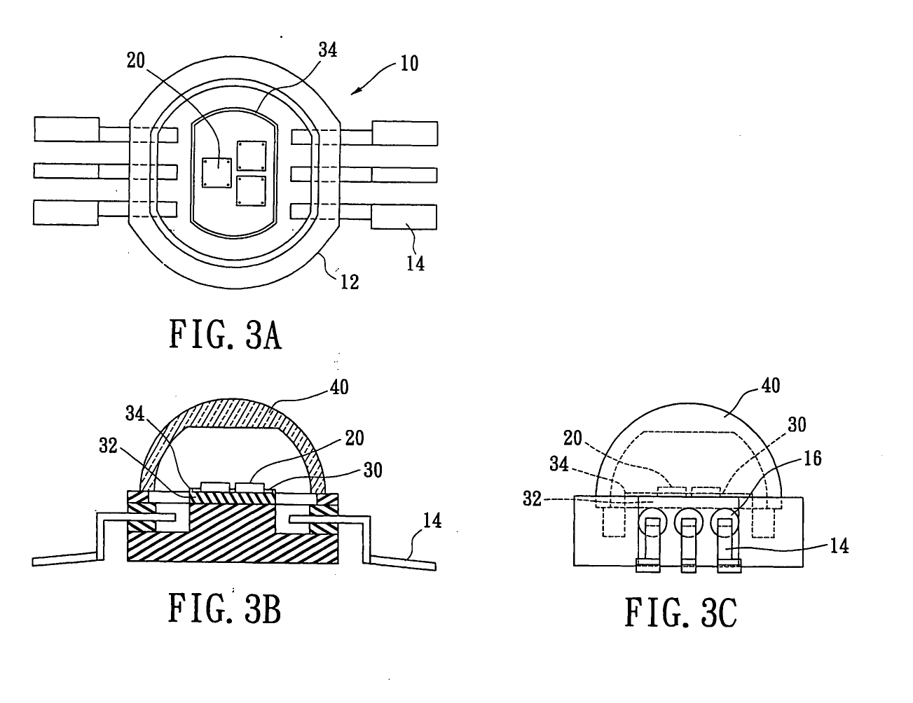

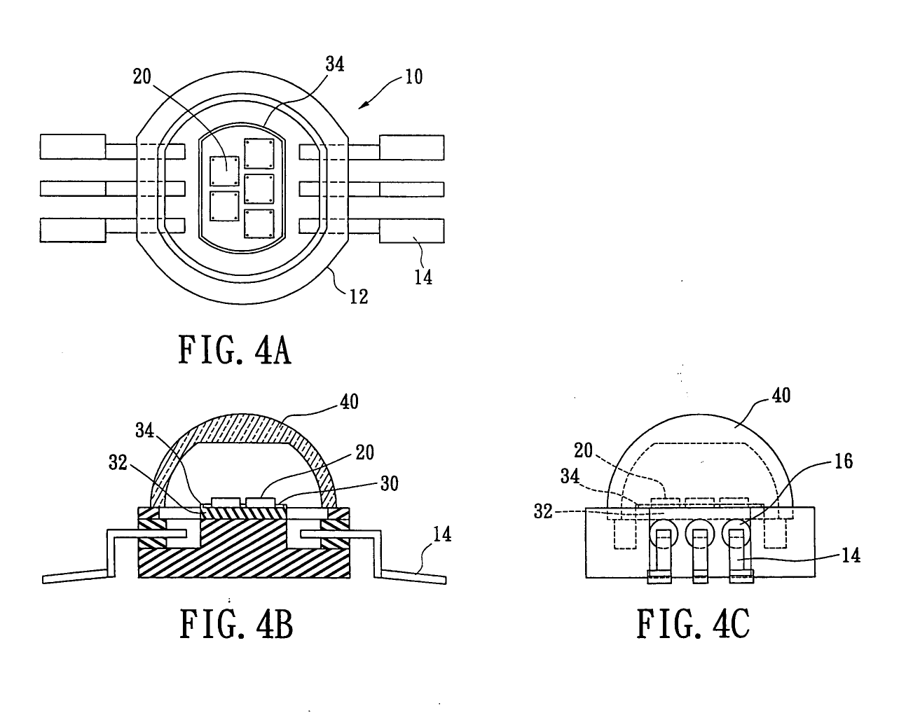

Reference is made to FIGS. 2A to 2C, 3A to 3C and 4A to 4C. Package structures of an optical-electrical semiconductor for the present invention are illustrated therein. The present invention comprises a shell body 10 having a heat conductive body 12 made of, for example, metal, ceramic or plastic and using a heat-conductive laminate or metal to transfer heat from top surface to bottom surface of the shell body 10, and lead 14. The shell body is integrally formed in one piece. The package structure also comprises a piece of heat-conductive laminate 30, an optical-electrical semiconductor structure 20 (can be multiple pieces) attached on the a plane of the internal side of the shell body 10 with heat conductive laminate 30, and a lens device 40 formed from a transparent material.

Heat conductive body 12 may directly connect to the lead with an electrical insulation connection style or heat conductive body 12 may indirectly connect to the lead 14 with an electrical insulation sleeve 16. The optical-electrical semiconductor structure 20 may have the ability to emit or detect light. The lens device 40 may be installed on heat conductive body 12 in a position facing the optical-electrical semiconductor structure 20. Also, the present invention may further comprises a substrate 32 (substrate 32 has outer ring 34) fixed on a surface inside heat conductive body 12. The optical-electrical semiconductor structure 20 may have a transparent polymer and electrical connection points, with the electrical connection points connected to a substrate in heat conductive body 12. The optical-electrical semiconductor structure 20 contains a light-emitting diode or photosensor. Heat conductive body 12 may be made of a polymer, and have heat conductive material forming a connection route to transfer heat from the optical-electrical semiconductor structure 20 to the bottom of the shell body. The heat conductive body 12 may be made of ceramic, with heat conductive material forming a connection route to transfer heat from the optical-electrical semiconductor structure to a bottom of the shell body. The shell body 10 maybe formed of metal. The optical-electrical semiconductor structure 20 has a bonding wire connected to the lead. The heat-conductive laminate may be silicon-containing material or metal material. The shell body 10 is formed by metal injection modeling, and the electrical insulation sleeve envelopes the lead to insulate electrically the lead 14 from heat conductive body 12. The substrate may be made of polymer, and the substrate may have capacitors or resistors embedded therein. The arrangement method of the optical-electrical semiconductor structure may be an average distribution in a special plane inside the heat-conductive body.

The major feature and the convenience of the present invention is to eliminate the cup wall to cause the light quality to be raised in a local light concentration area and integrally form the package in one piece for easy assembly. In addition, the present invention is cheaply made on conventional assembly equipment.

The present has these benefits: 1) production equipment requirement of the present invention is low cost and ease to achieve; 2) easy assembly because the package is integrally formed in one body; 3) most of the conventional package equipment also can be applied in the present invention; and 4) good light radiation quality.

Above is the optimal implementation of invention. It will be apparent that various changes and modifications can be made without departing from the scope of the invention as defined in the claims.

I claim:

1. A package structure of an optical-electrical semiconductor, comprising:
a shell body having a heat conductive body and lead, wherein the shell body is integrally formed in one piece;
a piece of heat-conductive laminate;
an optical-electrical semiconductor structure being attached on a plane of the internal side of the shell body with the heat conductive laminate; and
a lens device formed of transparent material.

2. The package structure of an optical-electrical semiconductor as claimed in claim 1, wherein the heat conductive body is directly connected to the lead by an electrical insulation connection or the heat conductive body is indirectly connected to the lead with an electrical insulation sleeve, wherein the optical-electrical semiconductor structure has the ability to emit light or detect light, and wherein the lens device is installed on the heat conductive body in a position facing the optical-electrical semiconductor structure.

3. The package structure of an optical-electrical semiconductor as claimed in claim 1, further comprising a substrate fixed on a surface inside the heat conductive body, wherein the optical-electrical semiconductor structure has transparent polymer and electrical connection points, and the electrical connection points connect to a substrate in the heat conductive body.

4. The package structure of an optical-electrical semiconductor as claimed in claim 1, wherein the optical-electrical semiconductor structure contains a light-emitting diode or photo sensor.

5. The package structure of an optical-electrical semiconductor as claimed in claim 1, wherein the heat conductive body is made of a polymer, and has heat conductive material to form a connection route to transfer heat from the optical-electrical semiconductor structure to a bottom of the shell body.

6. The package structure of an optical-electrical semiconductor as claimed in claim 1, wherein the heat conductive body is made of a ceramic material, and has heat conductive material to form a connection route to transfer heat from the optical-electrical semiconductor structure to a bottom of the shell body.

7. The package structure of an optical-electrical semiconductor as claimed in claim 1, wherein the shell body is formed of metal.

8. The package structure of an optical-electrical semiconductor as claimed in claim 1, wherein optical-electrical semiconductor structure has bonding wire connected to the lead.

9. The package structure of an optical-electrical semiconductor as claimed in claim 1, wherein the heat-conductive laminate is a silicon-containing material or metal material.

10. The package structure of an optical-electrical semiconductor as claimed in claim 1, wherein the shell body is formed by metal injection modeling, and the electrical insulation sleeve envelopes the lead to insulate electrically the lead from the heat conductive body.

11. The package structure of an optical-electrical semiconductor as claimed in claim 3, wherein the substrate is made of a polymer, and capacitors or resistors are embedded in the substrate.

12. The package structure of an optical-electrical semiconductor as claimed in claim 1, wherein an arrangement method of the optical-electrical semiconductor structure is by average distributing in a special plane inside heat conductive body.
